(19) United States
(12) Patent Application Publication
(10) Pub. No.: US 2018/0090476 A1
(43) Pub. Date: Mar. 29, 2018

(54) COMPOUND SEMICONDUCTOR DEVICE AND METHOD OF MANUFACTURING THE SAME

(71) Applicant: FUJITSU LIMITED, Kawasaki-shi (JP)

(72) Inventor: Youichi KAMADA, Yamato (JP)

(73) Assignee: FUJITSU LIMITED, Kawasaki-shi (JP)

(21) Appl. No.: 15/681,721

(22) Filed: Aug. 21, 2017

(30) Foreign Application Priority Data
Sep. 28, 2016 (JP) 2016-189834

(51) Int. Cl. H01L 27/02; H01L 27/095; H01L 29/40; H01L 29/778; H01L 21/8232; H01L 29/66; H01L 29/417; H03F 3/213; H03F 1/30; H02M 5/458

(52) U.S. Cl. CPC H01L 27/0211; H01L 27/095; H01L 29/404; H01L 29/7787; H01L 21/8232; H01L 29/2003; H01L 29/41775; H01L 29/41758; H03F 3/213; H03F 1/306; H02M 5/458; H01L 29/66462

(57) ABSTRACT

A compound semiconductor device includes transistors each including a gate electrode, a source electrode, and a drain electrode, wherein out of the transistors, a transistor whose temperature becomes higher during operation has a higher withstand voltage prior to temperature rise due to the operation.

### CROSS-REFERENCE TO RELATED APPLICATION

This application is based upon and claims the benefit of priority of the prior Japanese Patent Application No. 2016-189834, filed on Sep. 28, 2016, the entire contents of which are incorporated herein by reference.

### FIELD

The embodiments discussed herein are directed to a compound semiconductor device, a method of manufacturing the same.

### BACKGROUND

Nitride semiconductors have characteristics such as high saturation electron velocity and a wide band gap. Accordingly, various studies are being made on the application of nitride semiconductors to high withstand voltage and high power semiconductor devices utilizing these characteristics. For example, a high electron mobility transistor (HEMT) including a GaN-based nitride semiconductor is suitable for radio communication facilities such as base stations.

HEMT, however, generates heat while in high-frequency operation, and as its temperature becomes higher, its withstand voltage is apt to deteriorate. Though arts intended to improve heat dissipation efficiency of HEMT have been proposed, it cannot be said that these arts sufficiently prevent the withstand voltage deterioration due to the heat generation during the high-frequency operation.

Patent Literature 1: Japanese Laid-Open Patent Publication No. 2011-155164

### SUMMARY

According to an aspect of the embodiments, a compound semiconductor device includes transistors each including a gate electrode, a source electrode, and a drain electrode, wherein out of the transistors, a transistor whose temperature becomes higher during operation has a higher withstand voltage prior to temperature rise due to the operation.

According to another aspect of the embodiments, a method of manufacturing a compound semiconductor device includes forming transistors each including a gate electrode, a source electrode, and a drain electrode, wherein out of the transistors, a transistor whose temperature becomes higher during operation has a higher withstand voltage prior to temperature rise due to the operation.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a diagram illustrating a positional relation of electrodes in a compound semiconductor device according to a first embodiment;

FIG. 2 is a sectional view illustrating a structure of the compound semiconductor device according to the first embodiment;

FIG. 3 is a diagram illustrating a distribution of temperature during operation;

FIG. 4A is a diagram illustrating a relation between drain voltage and drain current at normal temperature in the first embodiment;

FIG. 4B is a diagram illustrating a relation between drain voltage and drain current at higher temperature in the first embodiment;

FIG. 4C is a diagram illustrating a relation between drain voltage and drain current at higher temperature in a reference;

FIG. 5A to FIG. 5E are process-by-process sectional views illustrating a method of manufacturing the compound semiconductor device according to the first embodiment;

FIG. 6 is a diagram illustrating a positional relation of electrodes in a compound semiconductor device according to a second embodiment;

FIG. 7 is a sectional view illustrating a structure of the compound semiconductor device according to the second embodiment;

FIG. 8A to FIG. 8D are process-by-process sectional views illustrating a method of manufacturing the compound semiconductor device according to the second embodiment;

FIG. 9 is a diagram illustrating a positional relation of electrodes in a compound semiconductor device according to a third embodiment;

FIG. 10 is a sectional view illustrating a structure of the compound semiconductor device according to the third embodiment;

FIG. 11 is a diagram illustrating a positional relation of electrodes in a compound semiconductor device according to a fourth embodiment;

FIG. 12 is a sectional view illustrating a structure of the compound semiconductor device according to the fourth embodiment;

FIG. 13 is a diagram illustrating a positional relation of electrodes in a compound semiconductor device according to a fifth embodiment;

FIG. 14 is a diagram illustrating a positional relation of electrodes in a compound semiconductor device according to a sixth embodiment;

FIG. 15 is a diagram illustrating a positional relation of electrodes in a compound semiconductor device according to a seventh embodiment;

FIG. 16 is a diagram illustrating a positional relation of electrodes in a compound semiconductor device according to an eighth embodiment;

FIG. 17 is a view illustrating a discrete package according to a ninth embodiment;

FIG. 18 is a wiring diagram illustrating a PFC circuit according to a tenth embodiment;

FIG. 19 is a wiring diagram illustrating a power supply apparatus according to an eleventh embodiment; and

FIG. 20 is a wiring diagram illustrating an amplifier according to a twelfth embodiment.

### DESCRIPTION OF EMBODIMENTS

The inventor of the present invention has studied why the withstand voltage deterioration due to the heat generation during the high-frequency operation cannot be sufficiently prevented in a conventional HEMT. The results of the studies have led to the findings that, in a semiconductor chip including HEMTs, the HEMTs have a higher temperature at its central portion than at its peripheral edge portion, and the withstand voltage deterioration of the central portion causes the withstand voltage deterioration of the semiconductor chip. It has been also found out that the withstand voltage deterioration of the central portion is noticeable especially in a finger gate-type semiconductor chip, in which gate electrodes, source electrodes, and drain electrodes are aligned a comb-teeth shape. Based on these findings, the inventor of the present invention has reached the following various forms.

Hereinafter, embodiments will be specifically described with reference to the accompanying drawings.

### First Embodiment

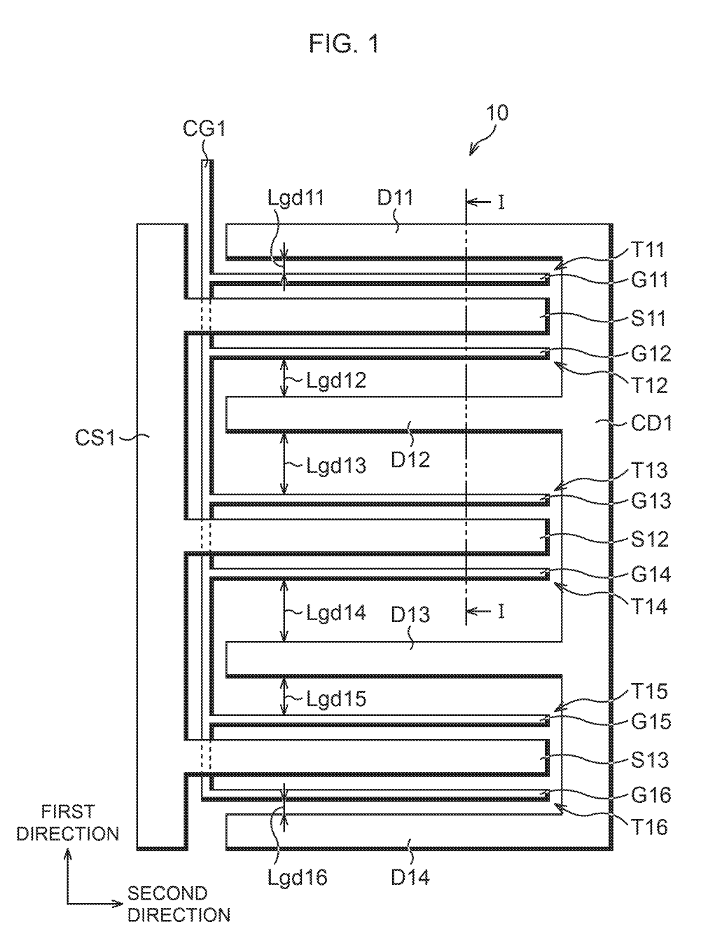

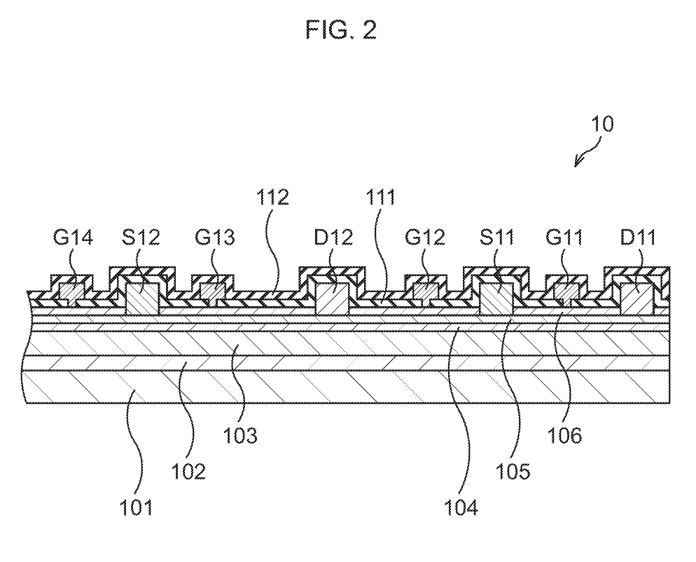

First, a first embodiment will be described. The first embodiment relates to an example of a compound semiconductor device including HEMTs. FIG. 1 is a diagram illustrating a positional relation of electrodes in the compound semiconductor device according to the first embodiment, and FIG. 2 is a sectional view illustrating a structure of the compound semiconductor device according to the first embodiment. FIG. 2 illustrates a cross section taken along the I-I line in FIG. 1.

As illustrated in FIG. 1, the compound semiconductor device 10 according to the first embodiment includes gate electrodes G11, G12, G13, G14, G15, and G16, source electrodes S11, S12, and S13, and drain electrodes D11, D12, D13, and D14. The gate electrodes G11 to G16 are connected commonly to a gate connection part CG1 and extend in parallel with one another from the gate connection part CG1. The source electrodes S11 to S13 are connected commonly to a source connection part CS1 and extend in parallel with the gate electrodes G11 to G16 from the source connection part CS1. The drain electrodes D11 to D14 are connected commonly to a drain connection part CD1 and extend in parallel with the gate electrodes G11 to G16 from the drain connection part CD1.

The source electrode S11 is between the drain electrode D11 and the drain electrode D12, the source electrode S12 is between the drain electrode D12 and the drain electrode D13, and the source electrode S13 is between the drain electrode D13 and the drain electrode D14. The gate electrode G11 is between the drain electrode D11 and the source electrode S11, the gate electrode G12 is between the source electrode S11 and the drain electrode D12, the gate electrode G13 is between the drain electrode D12 and the source electrode S12, the gate electrode G14 is between the source electrode S12 and the drain electrode D13, the gate electrode G15 is between the drain electrode D13 and the source electrode S13, and the gate electrode G16 is between the source electrode S13 and the drain electrode D14. That is, the gate electrodes G13 and G14 are between the gate electrode G12 and the gate electrode G15, and the gate electrodes G12 to G15 are between the gate electrode G11 and the gate electrode G16.

The gate electrode G11, the source electrode S11, and the drain electrode D11 are included in one transistor (HEMT) T11, the gate electrode G12, the source electrode S11, and the drain electrode D12 are included in one transistor (HEMT) T12, the gate electrode G13, the source electrode S12, and the drain electrode D12 are included in one transistor (HEMT) T13, the gate electrode G14, the source electrode S12, and the drain electrode D13 are included in one transistor (HEMT) T14, the gate electrode G15, the source electrode D13, and the drain electrode D13 are included in one transistor (HEMT) T15, and the gate electrode G16, the source electrode S13, and the drain electrode D14 are included in one transistor (HEMT) T16. The transistors T11 to T16 are aligned in parallel with a first direction, and the gate electrodes G11 to G16, the source electrodes S11 to S13, and the drain electrodes D11 to D14 extend in parallel with a second direction perpendicular to the first direction.

A distance Lgd11 between the gate electrode G11 and the drain electrode D11 is constant, a distance Lgd12 between the gate electrode G12 and the drain electrode D12 is constant, a distance Lgd13 between the gate electrode G13 and the drain electrode D12 is constant, a distance Lgd14 between the gate electrode G14 and the drain electrode D13 is constant, a distance Lgd15 between the gate electrode G15 and the drain electrode D13 is constant, and a distance Lgd16 between the gate electrode G16 and the drain electrode D14 is constant. The distance Lgd12 is larger than the distance Lgd11, the distance Lgd13 is larger than the distance Lgd12, the distance Lgd14 is equal to the distance Lgd13, the distance Lgd15 is smaller than the distance Lgd14, and the distance Lgd16 is smaller than the distance Lgd15. The distance between the gate electrode and the drain electrode refers to a distance between a drain electrode-side end portion of the lowest surface of the gate electrode (in this embodiment, a surface in contact with a cap layer 106) and a gate electrode-side end portion of the lowest surface of the drain electrode (in this embodiment, a surface in contact with a carrier supply layer 105) in planar view.

As illustrated in FIG. 2, the compound semiconductor device 10 includes a substrate 101, a buffer layer 102 over the substrate 101, and a carrier transit layer 103 over the buffer layer 102. The compound semiconductor device 10 also includes a spacer layer 104 over the carrier transit layer 103, the carrier supply layer 105 over the spacer layer 104, and the cap layer 106 over the carrier supply layer 105.

The substrate 101 is, for example, a SiC substrate. The buffer layer 102 is, for example, an AlGaN layer. The buffer layer 102 may include a superlattice structure. The carrier transit layer 103 is, for example, a GaN layer (i-GaN layer) having an about 3 μm thickness and not containing intentionally doped impurities. The spacer layer 104 is, for example, an AlGaN layer (i-AlGaN layer) having an about 5 nm thickness and not containing intentionally doped impurities. The carrier supply layer 105 is, for example, an n-type AlGaN layer (n-AlGaN layer) having an about 30 nm thickness. The cap layer 106 is, for example, an n-type GaN layer (n-GaN layer) having an about 10 nm thickness. The carrier supply layer 105 and the cap layer 106 are doped with, for example, Si with an about 5×10¹⁸ cm⁻³ concentration.

The cap layer 106 has therein openings for source electrodes and openings for drain electrodes, and the source electrodes S11 to S13 are in the openings for source electrodes and the drain electrodes D11 to D14 are in the openings for drain electrodes. An insulating film 111 covering the source electrodes S11 to S13 and the drain electrodes D11 to D14 is over the cap layer 106. The insulating film 111 has openings for gate electrodes therein, and the gate electrodes G11 to G16 in Schottky contact with the cap layer 106 through the openings for gate electrodes are included in the compound semiconductor device 10. An insulating film 112 covering the gate electrodes G11 to G16 is over the insulating film 111. A material of the insulating film 111 and the insulating film 112 is not limited, and for example, a silicon nitride film is used.

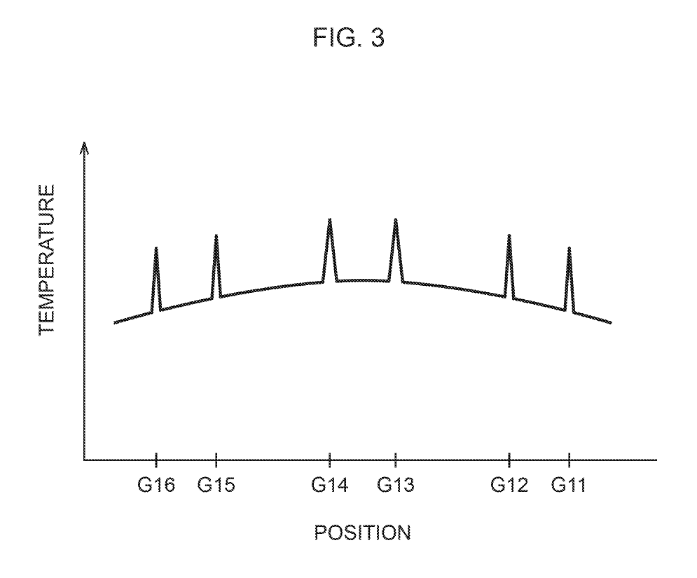

In the first embodiment thus structured, two-dimensional electron gas (2DEG) is generated near a surface of the carrier transit layer 103. Then, the transistors T11 to T16 generate heat while in operation, and the heat generated in the transistor T11 is more easily dissipated out than the heat generated in the transistor T12, and the heat generated in the transistor T12 is more easily dissipated out than the heat generated in the transistor T13. Similarly, the heat generated in the transistor T16 is more easily dissipated out than the heat generated in the transistor T15, and the heat generated in the transistor T15 is more easily dissipated out than the heat generated in the transistor T14. Therefore, as illustrated in FIG. 3, the temperature during the operation is the highest around the gate electrode G13 and around the gate electrode G14, and is the next highest around the gate electrode G12 and around the gate electrode G15.

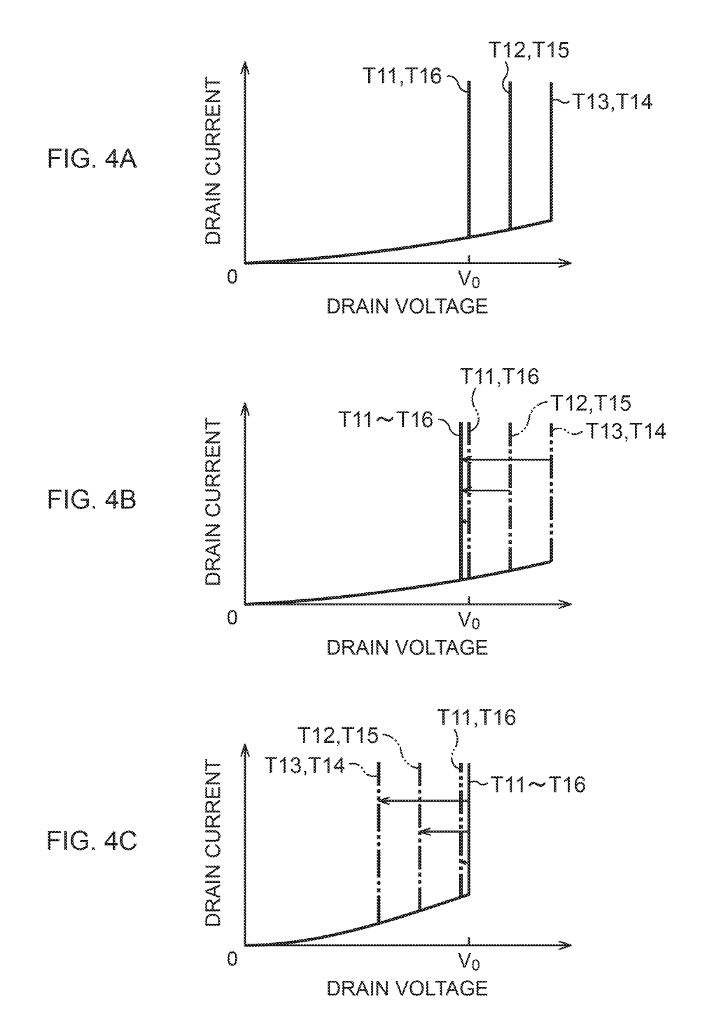

In the first embodiment, the distance Lgd12 is larger than the distance Lgd11, the distance Lgd13 is larger than the distance Lgd12, the distance Lgd14 is larger than the distance Lgd15, and the distance Lgd15 is larger than the distance Lgd16. Accordingly, when the temperature in the compound semiconductor device 10 is uniform, out of the transistors T11 to T16, the transistors T13 and T14 have the highest withstand voltage, and the transistors T12 and T15 have the next highest withstand voltage. That is, in the first embodiment, in a part where the temperature becomes higher during the operation, the distance between the gate electrode and the drain electrode is larger. This makes it possible for the transistors T12 to T15 to have a substantially equal withstand voltage to that of the transistors T11 and T16 even if there occurs a difference in a decrease amount of the withstand voltage due to a difference in temperature. This achieves excellent reliability. For example, where the characteristics illustrated in FIG. 4A are obtained at normal temperatures, even if the withstand voltage deteriorates due to a temperature rise due to the high-frequency operation, the transistors T11 to T16 can have a substantially equal withstand voltage as illustrated in FIG. 4B. If the distances Lgd12 to Lgd15 are equal to the distances Lgd11 and Lgd16, the withstand voltages of the transistors T12 to T15, the withstand voltages of the transistors T13 and T14 in particular, greatly decrease in accordance with a temperature rise as illustrated in FIG. 4C.

An increase of the distance between the gate electrode and the drain electrode leads to an increase of a chip area. Even if the distance between the gate electrode and the drain electrode in a part where the temperature during operation is relatively low is set about equal to that in a part where the temperature during the operation is relatively high, this does not lead to a further improvement of reliability of the compound semiconductor device 10. Accordingly, even if the distance between the gate electrode and the drain electrode in a part where the temperature is relatively low during the operation is set about equal to that in a part where the temperature is relatively high during the operation, this only results in an increase of the chip area.

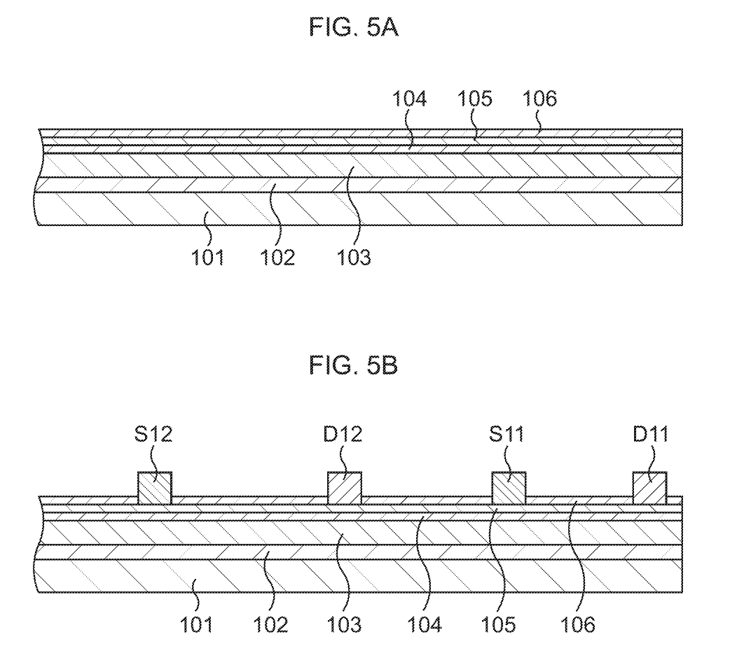

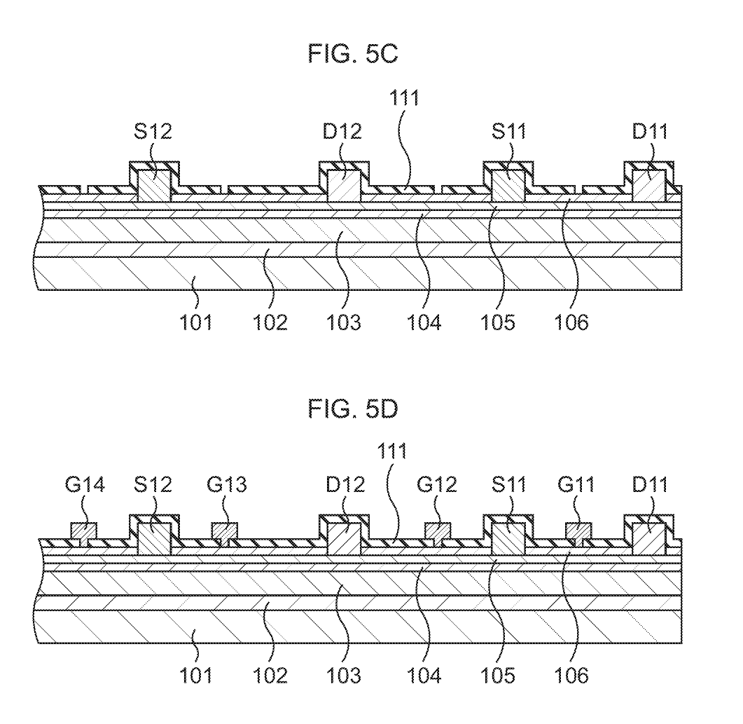

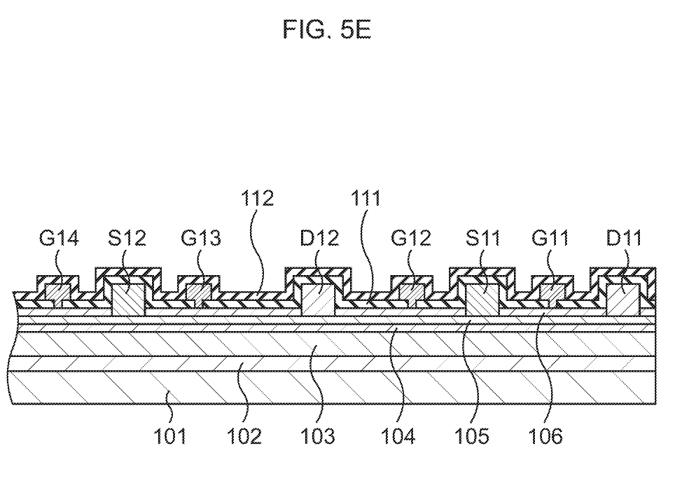

Next, an example of a method of manufacturing the compound semiconductor device according to the first embodiment will be described. FIG. 5A to FIG. 5E are process-by-process sectional views illustrating the example of the method of manufacturing the compound semiconductor device according to the first embodiment.

First, as illustrated in FIG. 5A, the buffer layer 102, the carrier transit layer 103, the spacer layer 104, the carrier supply layer 105, and the cap layer 106 are formed over the substrate 101. The buffer layer 102, the carrier transit layer 103, the spacer layer 104, the carrier supply layer 105, and the cap layer 106 may be formed by, for example, a metal organic vapor phase epitaxy (MOVPE) method. In forming these compound semiconductor layers, mixed gas of, for example, trimethylaluminum (TMA) gas, which is an Al source, trimethylgallium (TMG) gas, which is a Ga source, and ammonia (NH₃) gas, which is a N source is used. At this time, depending on the composition of the compound semiconductor layer to be grown, whether to supply the trimethylaluminum gas and the trimethylgallium gas or not, and flow rates thereof are appropriately controlled. The flow rate of the ammonia gas, which is a material commonly used for the compound semiconductor layers, is set to about 100 ccm to about 10 LM, for instance. For example, growth pressure is set to about 50 Torr to about 300 Torr, and growth temperature is set to about 1000° C. to about 1200° C. When the n-type compound semiconductor layer (for example, the carrier supply layer 105 and the cap layer 106) is grown, for example, SiH₄ gas containing Si is added to the mixed gas at a predetermined flow rate to dope the compound semiconductor layer with Si. The doping concentration of Si is about 1×10¹⁸ cm⁻³ to about 1×10²⁰ cm⁻³, for example, about 5×10¹⁸ cm⁻³.

Then, as illustrated in FIG. 5B, the openings for source electrodes and the openings for drain electrodes are formed in the cap layer 106 using a photolithography technique, and the source electrodes S11 to S13 are formed in the openings for source electrodes and the drain electrodes D11 to D14 are formed in the openings for drain electrodes. The source electrodes S11 to S13 and the drain electrodes D11 to D14 may be formed by, for example a lift-off method. Specifically, a photoresist pattern exposing regions where to form the source electrodes S11 to S13 and regions where to form the drain electrodes D11 to D14 and covering the other region is formed, a metal film is formed by a vapor deposition method with this pattern as a growth mask, and this pattern is removed together with the metal film thereon. In forming the metal film, for example, an Al film is formed after a Ti film is formed. Thereafter, heat treatment is performed at 400° C. to 900° C. (for example, 580° C.) in a nitrogen atmosphere to establish ohmic characteristics.

Subsequently, as illustrated in FIG. 5C, the insulating film 111 covering the source electrodes S11 to S13 and the drain electrodes D11 to D14 is formed over the cap layer 106. The insulating film 111 may be formed by, for example, a chemical vapor deposition (CVD) method, an atomic layer deposition (ALD) method, or a sputtering method. Then, the openings for gate electrodes are formed in the insulating film 111 using a photolithography technique. The openings for source electrodes, the openings for drain electrodes, and the openings for gate electrodes are formed such that the distance Lgd12 is larger than the distance Lgd11, the distance Lgd13 is larger than the distance Lgd12, the distance Lgd14 is equal to the distance Lgd13, the distance Lgd15 is smaller than the distance Lgd14, and the distance Lgd16 is smaller than the distance Lgd15.

Thereafter, as illustrated in FIG. 5D, the gate electrodes G11 to G16 are formed in the openings for gate electrodes. The gate electrodes G11 to G16 can be formed by, for example, a lift-off method. Specifically, a photoresist pattern exposing regions where to form the gate electrodes G11 to G16 are formed, a metal film is formed by a vapor deposition method with this pattern as a growth mask, and this pattern is removed together with the metal film thereon. In forming the metal film, for example, a Au film is formed after a Ni film is formed.

Subsequently, as illustrated in FIG. 5E, the insulating film 112 covering the gate electrodes G11 to G16 is formed over the insulating film 111. The insulating film 112 may be formed by, for example, a CVD method, an ALD method, or a sputtering method similarly to the insulating film 111.

Then, a protective film, wiring, and others are formed as required to complete the compound semiconductor device.

### Second Embodiment

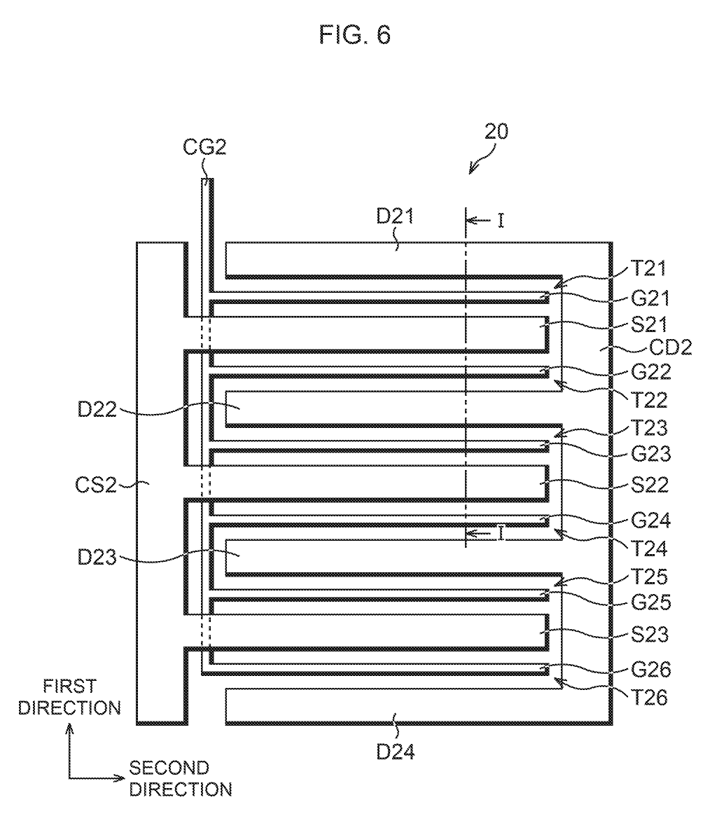

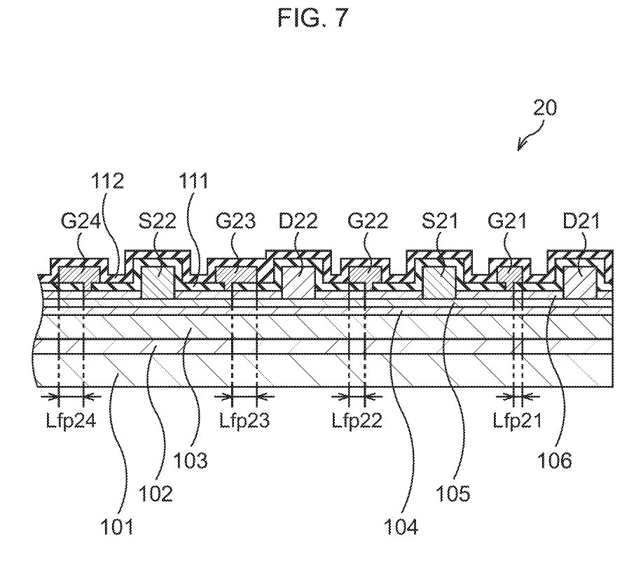

Next, a second embodiment will be described. The second embodiment relates to an example of a compound semiconductor device including HEMTs. FIG. 6 is a diagram illustrating a positional relation of electrodes in the compound semiconductor device according to the second embodiment, and FIG. 7 is a sectional view illustrating a structure of the compound semiconductor device according to the second embodiment. FIG. 7 illustrates a cross section taken along the I-I line in FIG. 6.

As illustrated in FIG. 6, the compound semiconductor device 20 according to the second embodiment includes gate electrodes G21, G22, G23, G24, G25, and G26, source electrodes S21, S22, and S23, and drain electrodes D21, D22, D23, and D24. The gate electrodes G21 to G26 are connected commonly to a gate connection part CG2 and extend in parallel with one another from the gate connection part CG2. The source electrodes S21 to S23 are connected commonly to a source connection part CS2 and extend in parallel with the gate electrodes G21 to G26 from the source connection part CS2. The drain electrodes D21 to D24 are connected commonly to a drain connection part CD2 and extend in parallel with the gate electrodes G21 to G26 from the drain connection part CD2.

The source electrode S21 is between the drain electrode D21 and the drain electrode D22, the source electrode S22 is between the drain electrode D22 and the drain electrode D23, and the source electrode S23 is between the drain electrode D23 and the drain electrode D24. The gate electrode G21 is between the drain electrode D21 and the source electrode S21, the gate electrode G22 is between the source electrode S21 and the drain electrode D22, the gate electrode G23 is between the drain electrode D22 and the source electrode S22, the gate electrode G24 is between the source electrode S22 and the drain electrode D23, the gate electrode G25 is between the drain electrode D23 and the source electrode S23, and the gate electrode G26 is between the source electrode S23 and the drain electrode D24. That is, the gate electrodes G23 and G24 are between the gate electrode G22 and the gate electrode G25, and the gate electrodes G22 to G25 are between the gate electrode G21 and the gate electrode G26.

The gate electrode G21, the source electrode S21, and the drain electrode D21 are included in one transistor (HEMT) T21, the gate electrode G22, the source electrode S21, and the drain electrode D22 are included in one transistor (HEMT) T22, the gate electrode G23, the source electrode S22, and the drain electrode D22 are included in one transistor (HEMT) T23, the gate electrode G24, the source electrode S22, and the drain electrode D23 are included in one transistor (HEMT) T24, the gate electrode G25, the source electrode D23, and the drain electrode D23 are included in one transistor (HEMT) T25, and the gate electrode G26, the source electrode S23, and the drain electrode D24 are included in one transistor (HEMT) T26. The transistors T21 to T26 are aligned in parallel with a first direction, and the gate electrodes G21 to G26, the source electrodes S21 to S23, and the drain electrodes D21 to D24 extend in parallel with a second direction perpendicular to the first direction.

A length Lfp21 of a drain electrode D21-side field plate portion of the gate electrode G21 is constant, a length Lfp22 of a drain electrode D22-side field plate portion of the gate electrode G22 is constant, a length Lfp23 of a drain electrode D22-side field plate portion of the gate electrode G23 is constant, a length Lfp24 of a drain electrode D23-side field plate portion of the gate electrode G24 is constant, a length Lfp25 of a drain electrode D23-side field plate portion of the gate electrode G25 is constant, and a length Lfp26 of a drain electrode D24-side field plate portion of the gate electrode G26 is constant. The field plate portions of the gate electrodes G21 to G26 are each an example of a first field plate portion. As illustrated in FIG. 7, the length Lfp22 is larger than the length Lfp21, the length Lfp23 is larger than the length Lfp22, and the length Lfp24 is equal to the length Lfp23. The length Lfp25 is smaller than the length Lfp24, and the length Lfp26 is smaller than the length Lfp25. The length of the drain electrode-side first field plate portion of the gate electrode refers to the length in a gate length direction (the first direction) of a portion that is on the drain electrode-side of the gate electrode and overlaps with an insulating film 111, in planar view.

As illustrated in FIG. 7, the compound semiconductor device 20 includes the substrate 101, the buffer layer 102 over the substrate 101, and the carrier transit layer 103 over the buffer layer 102. The compound semiconductor device 20 also includes the spacer layer 104 over the carrier transit layer 103, the carrier supply layer 105 over the spacer layer 104, and the cap layer 106 over the carrier supply layer 105.

The cap layer 106 has therein the openings for source electrodes and the openings for drain electrodes, and the source electrodes S21 to S23 are in the openings for source electrodes and the drain electrodes D21 to D24 are in the openings for drain electrodes. The insulating film 111 covering the source electrodes S21 to S23 and the drain electrodes D21 to D24 is over the cap layer 106. The insulating film 111 has therein the openings for gate electrodes, and the gate electrodes G21 to G26 in Schottky contact with the cap layer 106 through the openings for gate electrodes are included in the compound semiconductor device 20. The insulating film 112 covering the gate electrodes G21 to G26 is over the insulating film 111.

In the second embodiment thus structured, two-dimensional electron gas (2DEG) is generated near a surface of the carrier transit layer 103. Then, the transistor T21 to T26 generate heat while in operation, and the heat generated in the transistor T21 is more easily dissipated out than the heat generated in the transistor T22, and the heat generated in the transistor T22 is more easily dissipated out than the heat generated in the transistor T23. Similarly, the heat generated in the transistor T26 is more easily dissipated out than the heat generated in the transistor T25, and the heat generated in the transistor T25 is more easily dissipated out than the heat generated in the transistor T24. Therefore, the temperature during the operation is the highest around the gate electrode G23 and around the gate electrode G24, and is the next highest around the gate electrode G22 and around the gate electrode G25.

In the second embodiment, the length Lfp22 is larger than the length Lfp21, the length Lfp23 is larger than the length Lfp22, the length Lfp24 is larger than the length Lfp25, and the length Lfp25 is larger than the length Lfp26. Accordingly, when the temperature in the compound semiconductor device 20 is uniform, out of the transistors T21 to T26, the transistors T23 and T24 have the highest withstand voltage, and the transistors T22 and T25 have the next highest withstand voltage. That is, in the second embodiment, in a part where the temperature becomes higher during the operation, the first field plate portion is longer. This makes it possible for the transistors T22 to T25 to have a substantially equal withstand voltage to that of the transistors T21 and T26 even if there occurs a difference in a decrease amount of the withstand voltage due to a difference in temperature. This achieves excellent reliability.

Note that, in FIG. 6, which illustrates the positional relation of the electrodes, the difference in the length among the field plate portions is not reflected.

An increase of the length of the first field plate portion leads to a decrease of power. Even if the length of the first field plate portion in a part where the temperature during operation is relatively low is set about equal to that in a part where the temperature during the operation is relatively high, this does not lead to a further improvement of reliability of the compound semiconductor device 20. Accordingly, even if the length of the first field plate portion in a part where the temperature during the operation is relatively low is set about equal to that in a part where the temperature is relatively high during the operation, this only results in a decrease of power.

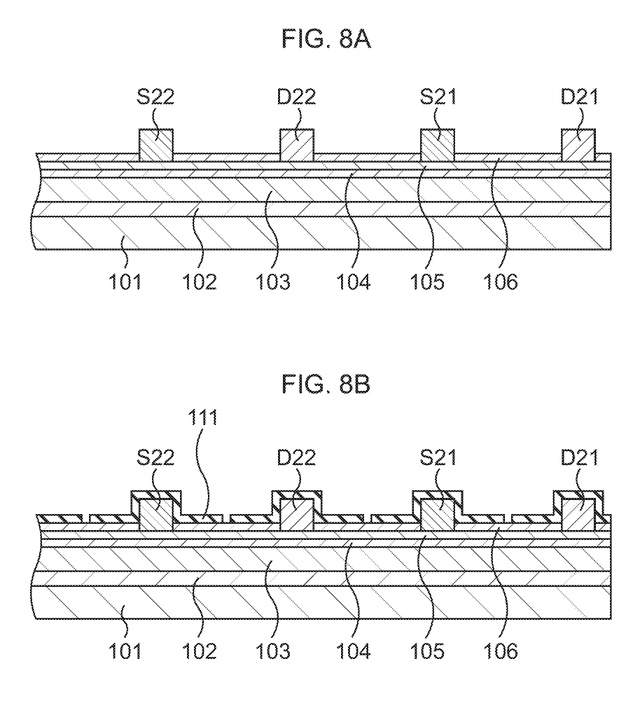

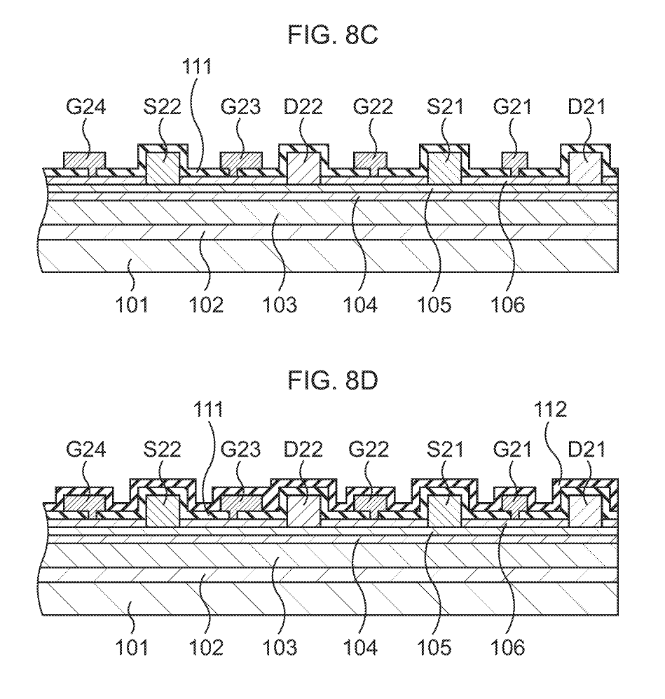

Next, an example of a method of manufacturing the compound semiconductor device according to the second embodiment will be described. FIG. 8A to FIG. 8D are process-by-process sectional views illustrating the example of the method of manufacturing the compound semiconductor device according to the second embodiment.

First, as illustrated in FIG. 8A, the buffer layer 102, the carrier transit layer 103, the spacer layer 104, the carrier supply layer 105, and the cap layer 106 are formed over the substrate 101 in the same manner as in the first embodiment. Then, the openings for source electrodes and the openings for drain electrodes are formed in the cap layer 106 using a photolithography technique, and the source electrodes S21 to S23 are formed in the openings for source electrodes and the drain electrodes D21 to D24 are formed in the openings for drain electrodes. Thereafter, heat treatment is performed at 400° C. to 900° C. (for example, 580° C.) in a nitrogen atmosphere to establish ohmic characteristics.

Subsequently, as illustrated in FIG. 8B, the insulating film 111 covering the source electrodes S21 to S23 and the drain electrodes D21 to D24 is formed on the cap layer 106. Then, the openings for gate electrodes are formed in the insulating film 111 using a photolithography technique.

Thereafter, as illustrated in FIG. 8C, the gate electrodes G21 to G26 are formed in the openings for gate electrodes. The gate electrodes G21 to G26 are formed such that the length Lfp22 is larger than the length Lfp21, the length Lfp23 is larger than the length Lfp22, the length Lfp24 is equal to the length Lfp23, the length Lfp25 is smaller than the length Lfp24, and the length Lfp26 is smaller than the length Lfp25.

Subsequently, as illustrated in FIG. 8D, the insulating film 112 covering the gate electrodes G21 to G26 is formed over the insulating film 111.

Then, a protective film, wiring, and others are formed as required to complete the compound semiconductor device.

### Third Embodiment

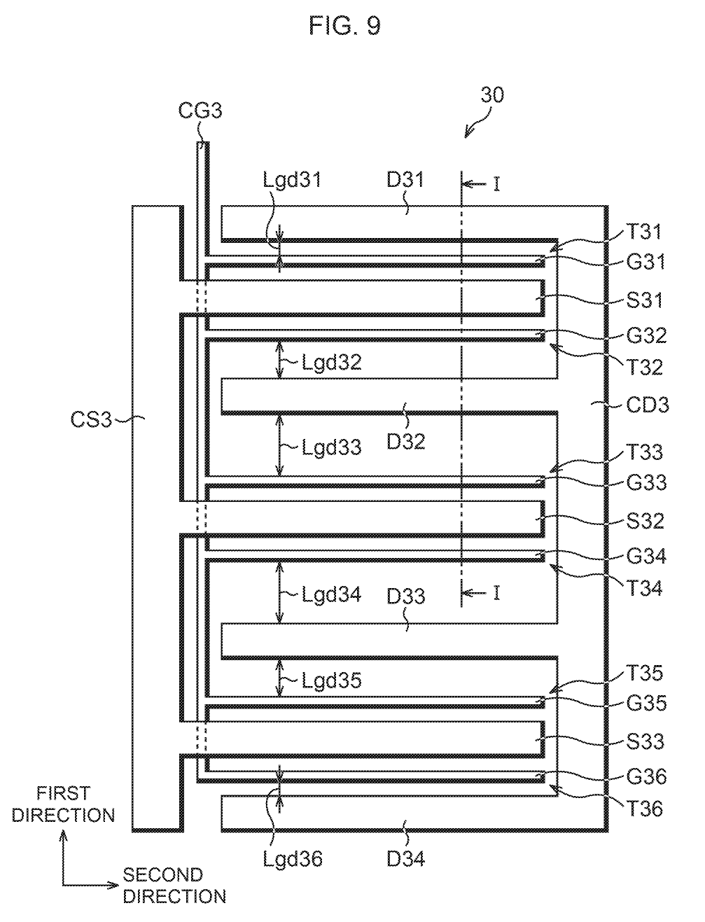

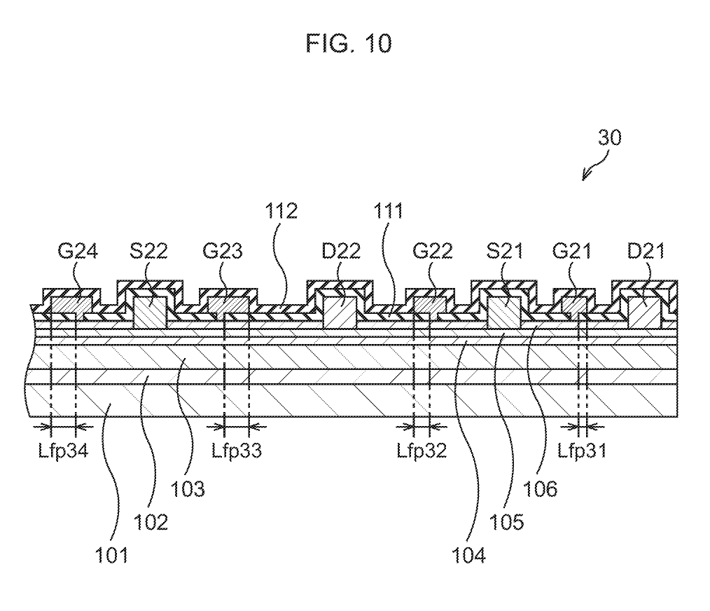

Next, a third embodiment will be described. The third embodiment relates to an example of a compound semiconductor device including HEMTs. FIG. 9 is a diagram illustrating a positional relation of electrodes in the compound semiconductor device according to the third embodiment, and FIG. 10 is a sectional view illustrating a structure of the compound semiconductor device according to the third embodiment. FIG. 10 illustrates a cross section taken along the I-I line in FIG. 9.

As illustrated in FIG. 9, the compound semiconductor device 30 according to the third embodiment includes gate electrodes G31, G32, G33, G34, G35, and G36, source electrodes S31, S32, and S33, and drain electrodes D31, D32, D33, and D34. The gate electrodes G31 to G36 are connected commonly to a gate connection part CG3 and extend in parallel with one another from the gate connection part CG3. The source electrodes S31 to S33 are connected commonly to a source connection part CS3 and extend in parallel with the gate electrodes G31 to G36 from the source connection part CS3. The drain electrodes D31 to D34 are connected commonly to a drain connection part CD3 and extend in parallel with the gate electrodes G31 to G36 from the drain connection part CD3.

The source electrode S31 is between the drain electrode D31 and the drain electrode D32, the source electrode S32 is between the drain electrode D32 and the drain electrode D33, and the source electrode S33 is between the drain electrode D33 and the drain electrode D34. The gate electrode G31 is between the drain electrode D31 and the source electrode S31, the gate electrode G32 is between the source electrode S31 and the drain electrode D32, the gate electrode G33 is between the drain electrode D32 and the source electrode S32, the gate electrode G34 is between the source electrode S32 and the drain electrode D33, the gate electrode G35 is between the drain electrode D33 and the source electrode S33, and the gate electrode G36 is between the source electrode S33 and the drain electrode D34. That is, the gate electrodes G32 to G35 are between the gate electrode G31 and the gate electrode G36.

The gate electrode G31, the source electrode S31, and the drain electrode D31 are included in one transistor (HEMT) T31, the gate electrode G32, the source electrode S31, and the drain electrode D32 are included in one transistor (HEMT) T32, the gate electrode G33, the source electrode S32, and the drain electrode D32 are included in one transistor (HEMT) T33, the gate electrode G34, the source electrode S32, and the drain electrode D33 are included in one transistor (HEMT) T34, the gate electrode G35, the source electrode D33, and the drain electrode D33 are included in one transistor (HEMT) T35, and the gate electrode G36, the source electrode S33, and the drain electrode D34 are included in one transistor (HEMT) T36. The transistors T31 to T36 are aligned in parallel with a first direction, and the gate electrodes G31 to G36, the source electrodes S31 to S33, and the drain electrodes D31 to D34 extend in parallel with a second direction perpendicular to the first direction.

A distance Lgd31 between the gate electrode G31 and the drain electrode D31 is constant, a distance Lgd32 between the gate electrode G32 and the drain electrode D32 is constant, a distance Lgd33 between the gate electrode G33 and the drain electrode D32 is constant, a distance Lgd34 between the gate electrode G34 and the drain electrode D33 is constant, a distance Lgd35 between the gate electrode G35 and the drain electrode D33 is constant, and a distance Lgd36 between the gate electrode G36 and the drain electrode D34 is constant. The distance Lgd32 is larger than the distance Lgd31, the distance Lgd33 is larger than the distance Lgd32, the distance Lgd34 is equal to the distance Lgd33, the distance Lgd35 is smaller than the distance Lgd34, and the distance Lgd36 is smaller than the distance Lgd35.

A length Lfp31 of a drain electrode D31-side field plate portion of the gate electrode G31 is constant, a length Lfp32 of a drain electrode D32-side field plate portion of the gate electrode G32 is constant, a length Lfp33 of a drain electrode D32-side field plate portion of the gate electrode G33 is constant, a length Lfp34 of a drain electrode D33-side field plate portion of the gate electrode G34 is constant, a length Lfp35 of a drain electrode D33-side field plate portion of the gate electrode G35 is constant, and a length Lfp36 of a drain electrode D34-side field plate portion of the gate electrode 36 is constant. As illustrated in FIG. 10, the length Lfp32 is larger than the length Lfp31, the length Lfp33 is larger than the length Lfp32, and the length Lfp34 is equal to the length Lfp33. The length Lfp35 is smaller than the length Lfp34, and the length Lfp36 is smaller than the length Lfp35.

As illustrated in FIG. 10, the compound semiconductor device 30 includes the substrate 101, the buffer layer 102 over the substrate 101, and the carrier transit layer 103 over the buffer layer 102. The compound semiconductor device 30 also includes the spacer layer 104 over the carrier transit layer 103, the carrier supply layer 105 over the spacer layer 104, and the cap layer 106 over the carrier supply layer 105.

The cap layer 106 has therein the openings for source electrodes and the openings for drain electrodes, and the source electrodes S31 to S33 are in the openings for source electrodes and the drain electrodes D31 to D34 are in the openings for drain electrodes. The insulating film 111 covering the source electrodes S31 to S33 and the drain electrodes D31 to D34 is over the cap layer 106. The insulating film 111 has therein the openings for gate electrodes, and the gate electrodes G31 to G36 in Schottky contact with the cap layer 106 through the openings for gate electrodes are included in the compound semiconductor device 30. The insulating film 112 covering the gate electrodes G31 to G36 is over the insulating film 111.

The third embodiment thus includes the combined structure of the first embodiment and the second embodiment. Accordingly, as in the first embodiment and the second embodiment, the transistors T32 to T35 can have a substantially equal withstand voltage to that of the transistors T31 and T36 even if there occurs a difference in a decrease amount of the withstand voltage due to a difference in temperature during operation. This achieves excellent reliability.

Note that, in FIG. 9, which illustrates the positional relation of the electrodes, the difference in the length among the field plate portions is not reflected.

In manufacturing the compound semiconductor device 30 according to the third embodiment, the layout of the compound semiconductor device 10 and the layout of the compound semiconductor device 20 are combined, for instance.

### Fourth Embodiment

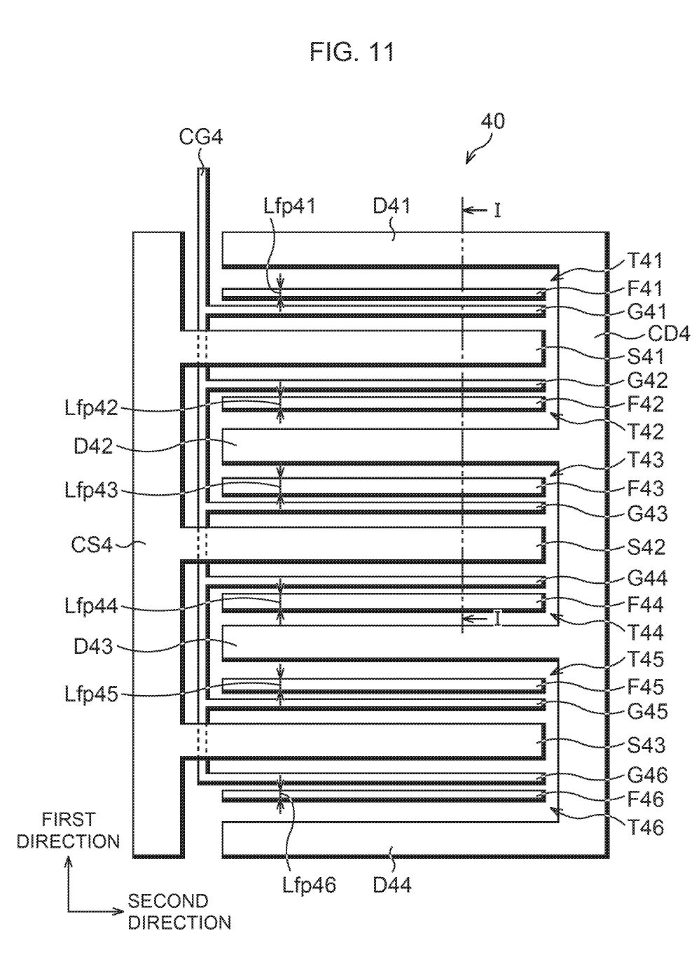

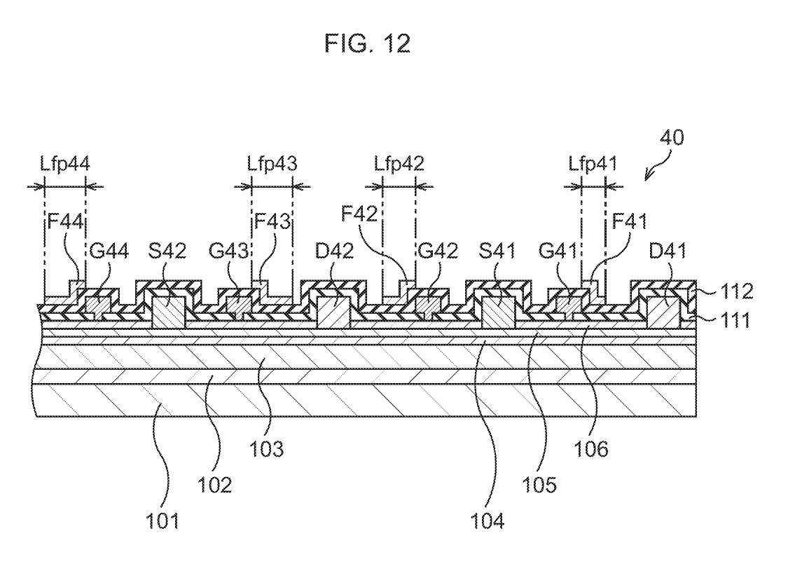

Next, a fourth embodiment will be described. The fourth embodiment relates to an example of a compound semiconductor device including HEMTs. FIG. 11 is a diagram illustrating a positional relation of electrodes in the compound semiconductor device according to the fourth embodiment, and FIG. 12 is a sectional view illustrating a structure of the compound semiconductor device according to the fourth embodiment. FIG. 12 illustrates a cross section taken along the I-I line in FIG. 11.

As illustrated in FIG. 11, the compound semiconductor device 40 according to the fourth embodiment includes gate electrodes G41, G42, G43, G44, G45, and G46, source electrodes S41, S42, and S43, and drain electrodes D41, D42, D43, and D44. The gate electrodes G41 to G46 are connected commonly to a gate connection part CG4 and extend in parallel with one another from the gate connection part CG4. The source electrodes S41 to S43 are connected commonly to a source connection part CS4 and extend in parallel with the gate electrodes G41 to G46 from the source connection part CS4. The drain electrodes D41 to D44 are connected commonly to a drain connection part CD4 and extend in parallel with the gate electrodes G41 to G46 from the drain connection part CD4.

The source electrode S41 is between the drain electrode D41 and the drain electrode D42, the source electrode S42 is between the drain electrode D42 and the drain electrode D43, and the source electrode S43 is between the drain electrode D43 and the drain electrode D44. The gate electrode G41 is between the drain electrode D41 and the source electrode S41, the gate electrode G42 is between the source electrode S41 and the drain electrode D42, the gate electrode G43 is between the drain electrode D42 and the source electrode S42, the gate electrode G44 is between the source electrode S42 and the drain electrode D43, the gate electrode G45 is between the drain electrode D43 and the source electrode S43, and the gate electrode G46 is between the source electrode S43 and the drain electrode D44. That is, the gate electrodes G43 and G44 are between the gate electrode G42 and the gate electrode G45, and the gate electrodes G42 to G45 are between the gate electrode G41 and the gate electrode G46.

The gate electrode G41, the source electrode S41, and the drain electrode D41 are included in one transistor (HEMT) T41, the gate electrode G42, the source electrode S41, and the drain electrode D42 are included in one transistor (HEMT) T42, the gate electrode G43, the source electrode S42, and the drain electrode D42 are included in one transistor (HEMT) T43, the gate electrode G44, the source electrode S42, and the drain electrode D43 are included in one transistor (HEMT) T44, the gate electrode G45, the source electrode S43, and the drain electrode D43 are included in one transistor (HEMT) T45, and the gate electrode G46, the source electrode S43, and the drain electrode D44 are included in one transistor (HEMT) T46. The transistors T41 to T46 are aligned in parallel with a first direction, and the gate electrodes G41 to G46, the source electrodes S41 to S43, and the drain electrodes D41 to D44 extend in parallel with a second direction perpendicular to the first direction.

As illustrated in FIG. 12, the compound semiconductor device 40 includes the substrate 101, the buffer layer 102 over the substrate 101, and the carrier transit layer 103 over the buffer layer 102. The compound semiconductor device 40 also includes the spacer layer 104 over the carrier transit layer 103, the carrier supply layer 105 over the spacer layer 104, and the cap layer 106 over the carrier supply layer 105.

The cap layer 106 has therein the openings for source electrodes and the openings for drain electrodes, and the source electrodes S41 to S43 are in the openings for source electrodes and the drain electrodes D41 to D44 are in the openings for drain electrodes. The insulating film 111 covering the source electrodes S41 to S43 and the drain electrodes D41 to D44 is over the cap layer 106. The insulating film 111 has therein the openings for gate electrodes, and the gate electrodes G41 to G46 in Schottky contact with the cap layer 106 through the openings for gate electrodes are included in the compound semiconductor device 40. The insulating film 112 covering the gate electrodes G41 to G46 is over the insulating film 111.

Field plate portions F41, F42, F43, F44, F45, and F46 are on the insulating film 111. The field plate portions F41 to F46 are insulated from the gate electrodes G41 to G46 by the insulating film 111. In planar view, the field plate portion F41 is between the gate electrode G41 and the drain electrode D41, the field plate portion F42 is between the gate electrode G42 and the drain electrode D42, the field plate portion F43 is between the gate electrode G43 and the drain electrode D42, the field plate portion F44 is between the gate electrode G44 and the drain electrode D43, the field plate portion F45 is between the gate electrode G45 and the drain electrode D43, and the field plate portion F46 is between the gate electrode G46 and the drain electrode D44. The field plate portion F41 is included in the transistor T41, the field plate portion F42 is included in the transistor T42, the field plate portion F43 is included in the transistor T43, the field plate portion F44 is included in the transistor T44, the field plate portion F45 is included in the transistor T45, and the field plate portion F46 is included in the transistor T46. The field plate portions F41 to F46 are grounded, for instance.

A length Lfp41 of the field plate portion F41 is constant, a length Lfp42 of the field plate portion F42 is constant, a length Lfp43 of the field plate portion F43 is constant, a length Lfp44 of the field plate portion F44 is constant, a length Lfp45 of the field plate portion F45 is constant, and a length Lfp46 of the field plate portion F46 is constant. The field plate portions F41 to F46 are each an example of a second field plate portion. As illustrated in FIG. 12, the length Lfp42 is larger than the length Lfp41, the length Lfp43 is larger than the length Lfp42, and the length Lfp44 is equal to the length Lfp43. The length Lfp45 is smaller than the length Lfp44, and the length Lfp46 is smaller than the length Lfp45. The length of the second field plate portion refers to the length in a gate length direction (the first direction) of the second field plate portion in planar view.

In the fourth embodiment thus structured, the length Lfp42 is larger than the length Lfp41, the length Lfp43 is larger than the length Lfp42, the length Lfp44 is larger than the length Lfp45, and the length Lfp45 is larger than the length Lfp46. Accordingly, when the temperature in the compound semiconductor device 40 is uniform, out of the transistors T41 to T46, the transistors T43 and T44 have the highest withstand voltage, and the transistors T42 and T45 have the next highest withstand voltage. That is, in the fourth embodiment, in a part where the temperature becomes higher during the operation, the second field plate portion is longer. This makes it possible for the transistors T42 to T45 to have a substantially equal withstand voltage to that of the transistors T41 and T46 even if there occurs a difference in a decrease amount of the withstand voltage due to a difference in temperature. This achieves excellent reliability.

An increase of the length of the second field plate portion leads to a decrease of power. Even if the length of the second field plate portion in a part where the temperature during operation is relatively low is set about equal to that in a part where the temperature during the operation is relatively high, this does not lead to a further improvement of reliability of the compound semiconductor device 40. Accordingly, even if the length of the second field plate portion in a part where the temperature during the operation is relatively low is set about equal to that in a part where the temperature is relatively high during the operation, this only results in a decrease of power.

In manufacturing the compound semiconductor device 40 according to the fourth embodiment, the field plate portions F41 to F46 are formed after the processes up to the formation of the insulating film 112 are carried out in the same manners as those in the first to third embodiments, for instance.

### Fifth Embodiment

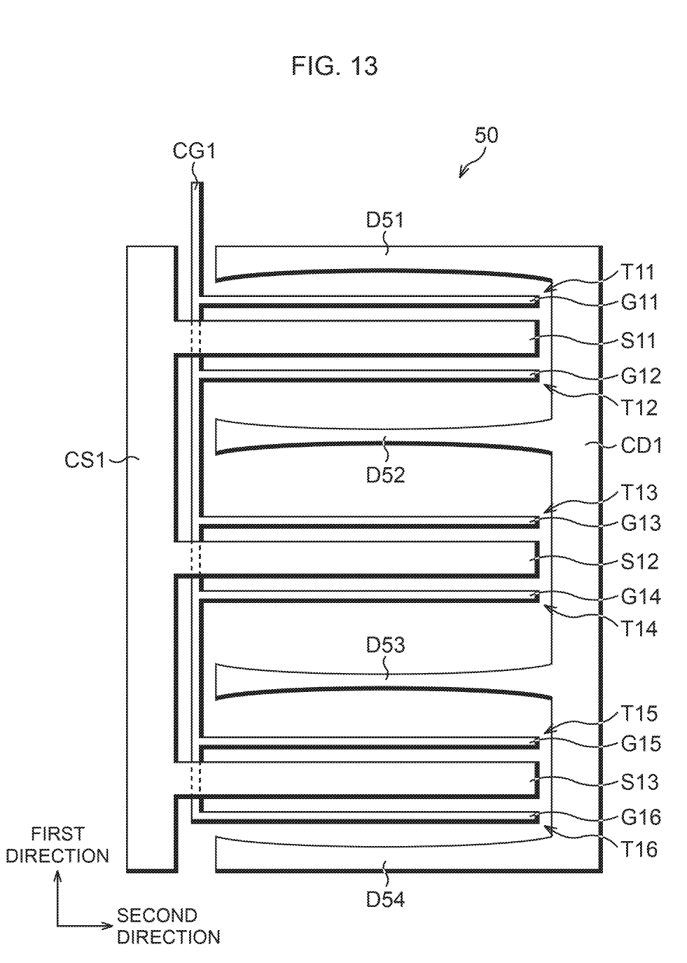

Next, a fifth embodiment will be described. The fifth embodiment relates to an example of a compound semiconductor device including HEMTs. FIG. 13 is a diagram illustrating a positional relation of electrodes in the compound semiconductor device according to the fifth embodiment.

As illustrated in FIG. 13, the compound semiconductor device 50 according to the fifth embodiment includes drain electrode D51 to D54 instead of the drain electrodes D11 to D14 in the first embodiment. In planar view, the drain electrode D51 has a shape such that its distance from the gate electrode G11 is larger as closer to the center thereof in its longitudinal direction (the second direction). In planar view, the drain electrode D52 has a shape such that its distance from the gate electrode G12 and its distance from the gate electrode G13 are larger as closer to the center thereof in its longitudinal direction (the second direction). In planar view, the drain electrode D53 has a shape such that its distance from the gate electrode G14 and its distance from the gate electrode G15 are larger as closer to the center thereof in its longitudinal direction (the second direction). In planar view, the drain electrode D54 has a shape such that its distance from the gate electrode G16 is larger as closer to the center thereof in its longitudinal direction (the second direction). The other structure is the same as that of the first embodiment.

Regarding the transistor T11, heat generated in its both ends is more easily dissipated out than heat generated in its center. Accordingly, the temperature during the operation is the highest around the center in a gate width direction (the second direction) and the lowest near the both ends. In the fifth embodiment, the drain electrode D51 has the shape such that its distance from the gate electrode G11 is larger as closer to the center in the gate width direction in planar view. Accordingly, even if there occurs a difference in a decrease amount of the withstand voltage in the transistor T11 due to a difference in the temperature during the operation, the withstand voltage around the center and that near the both ends can be substantially equal. As for the transistors T12 to T16 as well, the withstand voltage can be substantially uniform in each of the transistors. This achieves more excellent reliability.

### Sixth Embodiment

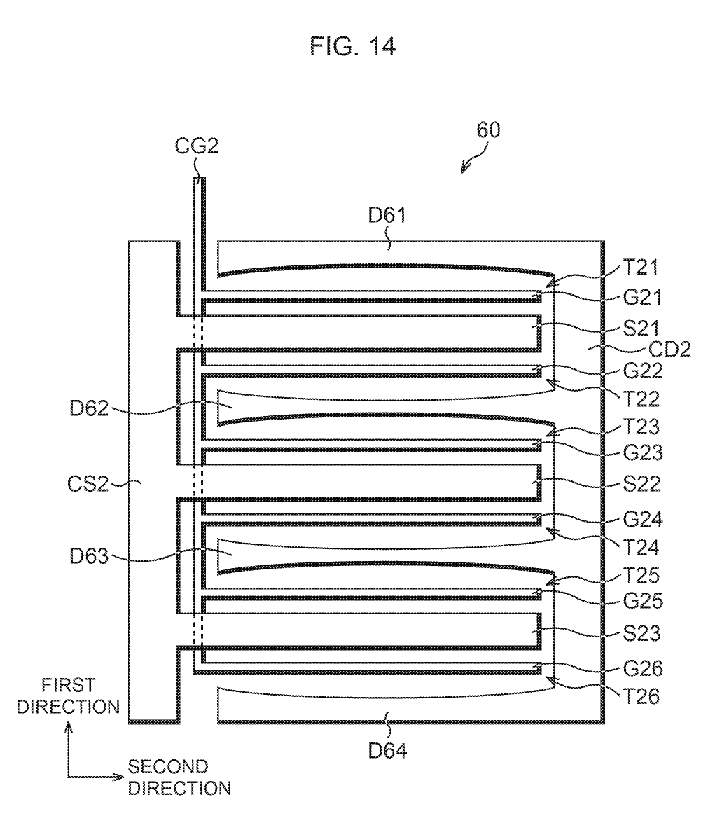

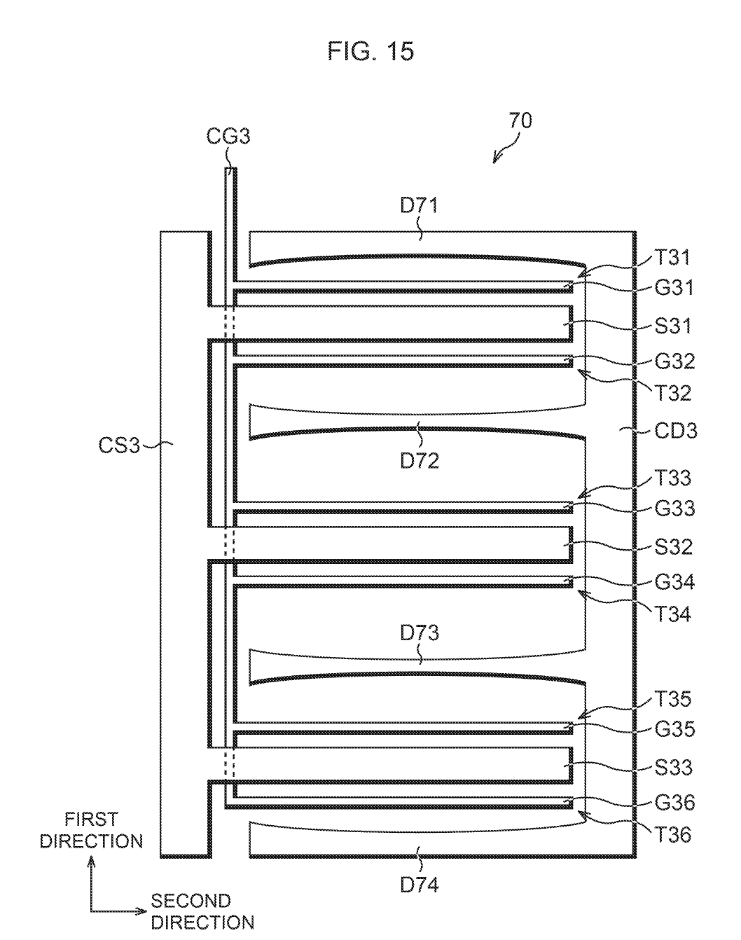

Next, a sixth embodiment will be described. The sixth embodiment relates to an example of a compound semiconductor device including HEMTs. FIG. 14 is a diagram illustrating a positional relation of electrodes in the compound semiconductor device according to the sixth embodiment.

As illustrated in FIG. 14, the compound semiconductor device 60 according to the sixth embodiment includes drain electrodes D61 to D64 instead of the drain electrodes D21 to D24 in the second embodiment. In planar view, the drain electrode D61 has a shape such that its distance from the gate electrode G21 is larger as closer to the center thereof in its longitudinal direction (the second direction). In planar view, the drain electrode D62 has a shape such that its distance from the gate electrode G22 and its distance from the gate electrode G23 are larger as closer to the center thereof in its longitudinal direction (the second direction). In planar view, the drain electrode D63 has a shape such that its distance from the gate electrode G24 and its distance from the gate electrode G25 are larger as closer to the center thereof in its longitudinal direction (the second direction). In planar view, the drain electrode D64 has a shape such that its distance from the gate electrode G26 is larger as closer to the center thereof in its longitudinal direction (the second direction). The other structure is the same as that of the second embodiment.

Regarding the transistor T21, heat generated in its both ends is more easily dissipated out than heat generated in its center. Accordingly, the temperature during the operation is the highest around the center in a gate width direction (the second direction) and the lowest near the both ends. In the sixth embodiment, the drain electrode D61 has the shape such that its distance from the gate electrode G21 is larger as closer to the center in the gate width direction in planar view. Accordingly, even if there occurs a difference in a decrease amount of the withstand voltage in the transistor T21 due to a difference in the temperature during the operation, the withstand voltage around the center and that near the both ends can be substantially equal. As for the transistors T22 to T26 as well, the withstand voltage can be substantially uniform in each of the transistors. This achieves more excellent reliability.

### Seventh Embodiment

Next, a seventh embodiment will be described. The seventh embodiment relates to an example of a compound semiconductor device including HEMTs. FIG. 15 is a diagram illustrating a positional relation of electrodes in the compound semiconductor device according to the seventh embodiment.

As illustrated in FIG. 15, the compound semiconductor device 70 according to the seventh embodiment includes drain electrodes D71 to D74 instead of the drain electrodes D31 to D34 in the third embodiment. In planar view, the drain electrode D71 has a shape such that its distance from the gate electrode G31 is larger as closer to the center thereof in its longitudinal direction (the second direction). In planar view, the drain electrode D72 has a shape such that its distance from the gate electrode G32 and its distance from the gate electrode G33 are larger as closer to the center thereof in its longitudinal direction (the second direction). In planar view, the drain electrode D73 has a shape such that its distance from the gate electrode G34 and its distance from the gate electrode G35 are larger as closer to the center thereof in its longitudinal direction (the second direction). In planar view, the drain electrode D74 has a shape such that its distance from the gate electrode G36 is larger as closer to the center thereof in its longitudinal direction (the second direction). The other structure is the same as that of the third embodiment.

Regarding the transistor T31, heat generated in its both ends is more easily dissipated out than heat generated in its center. Accordingly, the temperature during the operation is the highest around the center in a gate width direction (the second direction) and the lowest near the both ends. In the seventh embodiment, the drain electrode D71 has the shape such that its distance from the gate electrode G31 is larger as closer to the center thereof in the gate width direction in planar view. Accordingly, even if there occurs a difference in a decrease amount of the withstand voltage in the transistor T31 due to a difference in the temperature during the operation, the withstand voltage around the center and that near the both ends can be substantially equal. As for the transistors T32 to T36 as well, the withstand voltage can be substantially uniform in each of the transistors. This achieves more excellent reliability.

### Eighth Embodiment

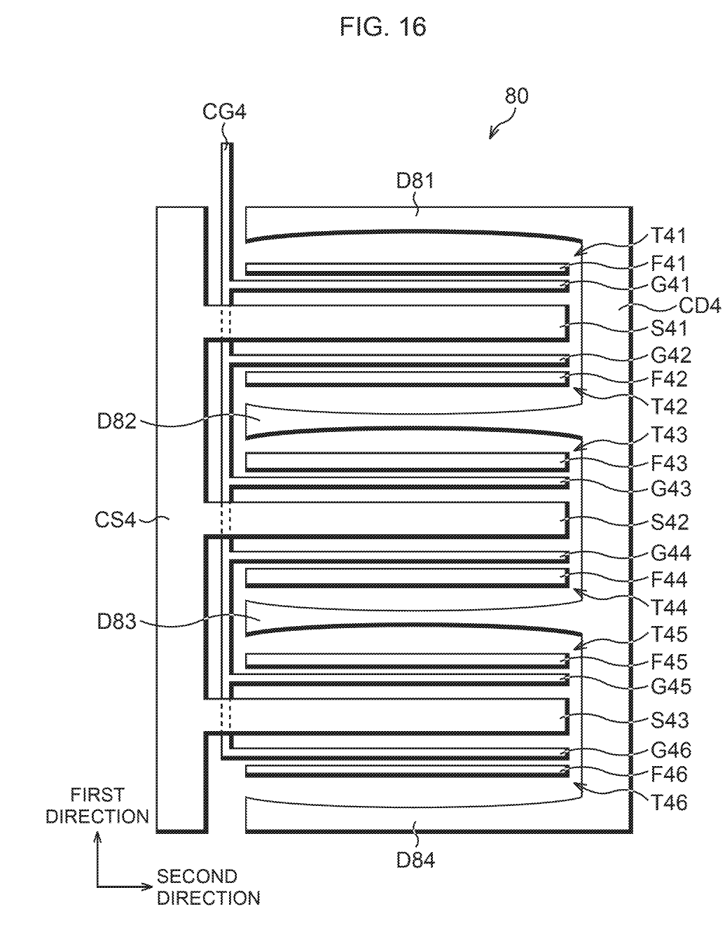

Next, an eighth embodiment will be described. The eighth embodiment relates to an example of a compound semiconductor device including HEMTs. FIG. 16 is a diagram illustrating a positional relation of electrodes in the compound semiconductor device according to the eighth embodiment.

As illustrated in FIG. 16, the compound semiconductor device 80 according to the eighth embodiment includes drain electrode D81 to D84 instead of the drain electrodes D41 to D44 in the fourth embodiment. In planar view, the drain electrode D81 has a shape such that its distance from the gate electrode G41 is larger as closer to the center thereof in its longitudinal direction (the second direction). In planar view, the drain electrode D82 has a shape such that its distance from the gate electrode G42 and its distance from the gate electrode G43 are larger as closer to the center thereof in its longitudinal direction (the second direction). In planar view, the drain electrode D83 has a shape such that its distance from the gate electrode G44 and its distance from the gate electrode G45 are larger as closer to the center thereof in its longitudinal direction (the second direction). In planar view, the drain electrode D84 has a shape such that its distance from the gate electrode G46 is larger as closer to the center thereof in its longitudinal direction (the second direction). The other structure is the same as that of the fourth embodiment.

Regarding the transistor T41, heat generated in its both ends is more easily dissipated out than heat generated in its center. Accordingly, the temperature during the operation is the highest around the center in a gate width direction (the second direction) and the lowest near the both ends. In the eighth embodiment, the drain electrode D81 has the shape such that its distance from the gate electrode G41 is larger as closer to the center thereof in the gate width direction in planar view. Accordingly, even if there occurs a difference in a decrease amount of the withstand voltage in the transistor T41 due to a difference in the temperature during the operation, the withstand voltage around the center and that near the both ends can be substantially equal. As for the transistors T42 to T46 as well, the withstand voltage can be substantially uniform in each of the transistors. This achieves more excellent reliability.

Similarly to that a part whose temperature becomes higher during the operation has a larger distance between the gate electrode and the drain electrode in the second direction in the fifth to eighth embodiments, a part whose temperature becomes higher during the operation may have a larger length of the first field plate portion in the second direction in each of the transistors in the second embodiment or the third embodiment. Similarly, in the fourth embodiment, a part whose temperature becomes higher during the operation may have a larger length of the second field plate portion in the second direction in each of the transistors. The field plate portions F41 to F46 may be included in the compound semiconductor device 10 according to the first embodiment.

### Ninth Embodiment

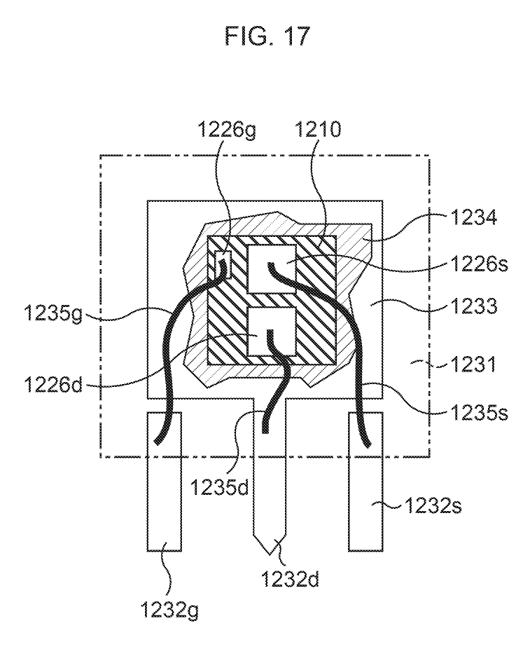

Next, a ninth embodiment is described. The ninth embodiment relates to a discrete package of a compound semiconductor device including HEMTs. FIG. 17 is a view illustrating the discrete package according to the ninth embodiment.

In the ninth embodiment, as illustrated in FIG. 17, a back surface of a HEMT chip 1210 of the compound semiconductor device including HEMTs according to any one of the first to eighth embodiments is fixed on a land (die pad) 1233, using a die attaching agent 1234 such as solder. One end of a wire 1235d such as an Al wire is bonded to a drain pad 1226d, to which one of the drain connection parts CD1 to CD4 is connected, and the other end of the wire 1235d is bonded to a drain lead 1232d integral with the land 1233. One end of a wire 1235s such as an Al wire is bonded to a source pad 1226s, to which one of the source connection parts CS1 to CS4 is connected, and the other end of the wire 1235s is bonded to a source lead 1232s separated from the land 1233. One end of a wire 1235g such as an Al wire is bonded to a gate pad 1226g, to which one of the drain connection parts CG1 to CG4 is connected, and the other end of the wire 1235g is bonded to a gate lead 1232g separated from the land 1233. The land 1233, the HEMT chip 1210 and so forth are packaged with a molding resin 1231, so as to project outwards a portion of the gate lead 1232g, a portion of the drain lead 1232d, and a portion of the source lead 1232s.

The discrete package may be manufactured by the procedures below, for example. First, the HEMT chip 1210 is bonded to the land 1233 of a lead frame, using a die attaching agent 1234 such as solder. Next, with the wires 1235g, 1235d and 1235s, the gate pad 1226g is connected to the gate lead 1232g of the lead frame, the drain pad 1226d is connected to the drain lead 1232d of the lead frame, and the source pad 1226s is connected to the source lead 1232s of the lead frame, respectively, by wire bonding. The molding with the molding resin 1231 is conducted by a transfer molding process. The lead frame is then cut away.

### Tenth Embodiment

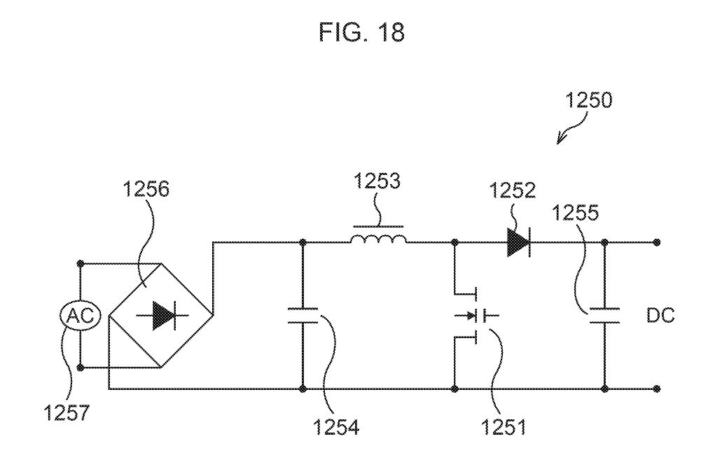

Next, a tenth embodiment is described. The tenth embodiment relates to a PFC (power factor correction) circuit equipped with a compound semiconductor device including HEMTs. FIG. 18 is a wiring diagram illustrating the PFC circuit according to the tenth embodiment.

A PFC circuit 1250 has a switching element (transistor) 1251, a diode 1252, a choke coil 1253, capacitors 1254 and 1255, a diode bridge 1256, and an AC power source (AC) 1257. The drain electrode of the switching element 1251, the anode terminal of the diode 1252, and one terminal of the choke coil 1253 are connected with each other. The source electrode of the switching element 1251, one terminal of the capacitor 1254, and one terminal of the capacitor 1255 are connected with each other. The other terminal of the capacitor 1254 and the other terminal of the choke coil 1253 are connected with each other. The other terminal of the capacitor 1255 and the cathode terminal of the diode 1252 are connected with each other. A gate driver is connected to the gate electrode of the switching element 1251. The AC 1257 is connected between both terminals of the capacitor 1254 via the diode bridge 1256. A DC power source (DC) is connected between both terminals of the capacitor 1255. In the embodiment, the compound semiconductor device including HEMTs according to any one of the first to eighth embodiments is used as the switching element 1251.

In the method of manufacturing the PFC circuit 1250, for example, the switching element 1251 is connected to the diode 1252, the choke coil 1253 and so forth with solder, for example.

### Eleventh Embodiment

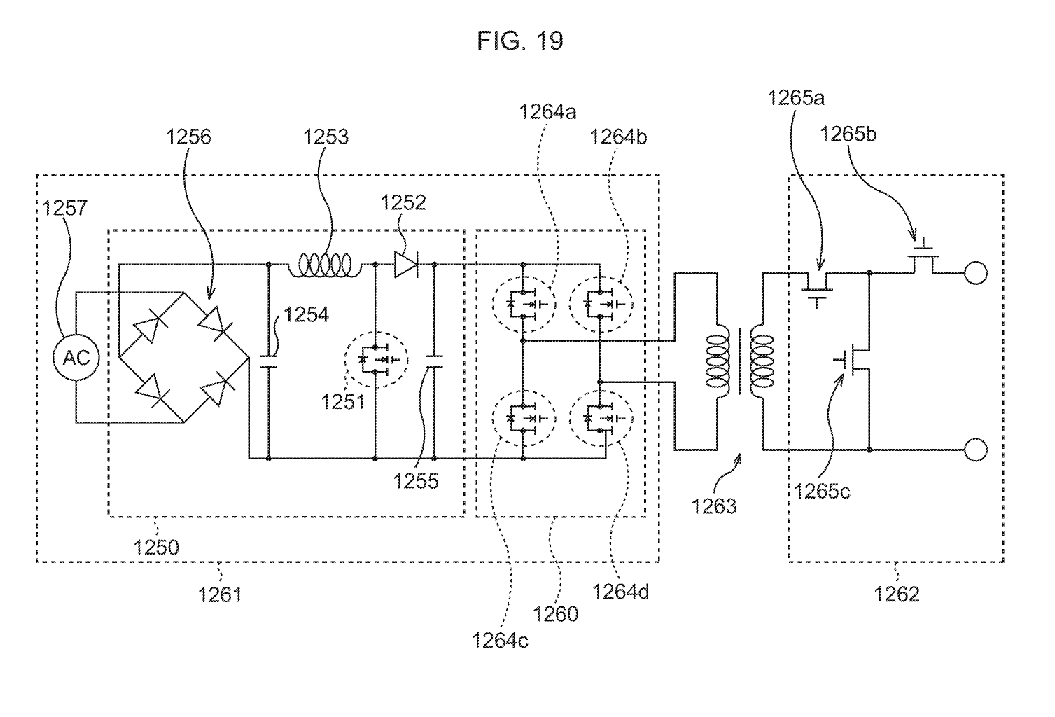

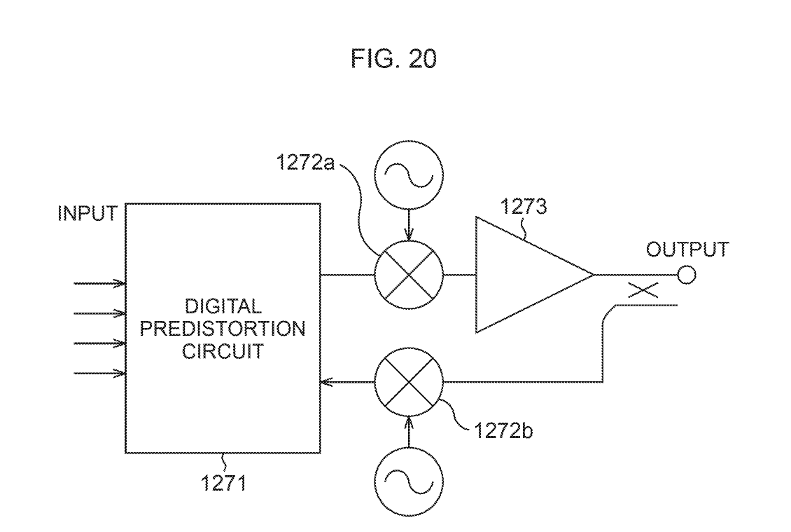

Next, an eleventh embodiment is described. The eleventh embodiment relates to a power supply apparatus equipped with a compound semiconductor device including HEMTs. FIG. 19 is a wiring diagram illustrating the power supply apparatus according to the eleventh embodiment.

The power supply apparatus includes a high-voltage, primary-side circuit 1261, a low-voltage, secondary-side circuit 1262, and a transformer 1263 arranged between the primary-side circuit 1261 and the secondary-side circuit 1262.

The primary-side circuit 1261 includes the PFC circuit 1250 according to the tenth embodiment, and an inverter circuit, which may be a full-bridge inverter circuit 1260, for example, connected between both terminals of the capacitor 1255 in the PFC circuit 1250. The full-bridge inverter circuit 1260 includes a plurality of (four, in the embodiment) switching elements 1264a, 1264b, 1264c and 1264d.

The secondary-side circuit 1262 includes a plurality of (three, in the embodiment) switching elements 1265a, 1265b and 1265c.

In the embodiment, the compound semiconductor device including HEMTs according to any one of the first to eighth embodiments is used for the switching element 1251 of the PFC circuit 1250, and for the switching elements 1264a, 1264b, 1264c and 1264d of the full-bridge inverter circuit 1260. The PFC circuit 1250 and the full-bridge inverter circuit 1260 are components of the primary-side circuit 1261. On the other hand, a silicon-based general MIS-FET (field effect transistor) is used for the switching elements 1265a, 1265b and 1265c of the secondary-side circuit 1262.

### Twelfth Embodiment

Next, a twelfth embodiment is explained. The twelfth embodiment relates to an amplifier equipped with a compound semiconductor device including HEMTs. FIG. 20 is a wiring diagram illustrating the amplifier according to the twelfth embodiment.

The amplifier includes a digital predistortion circuit 1271, mixers 1272a and 1272b, and a power amplifier 1273.

The digital predistortion circuit 1271 compensates non-linear distortion in input signals. The mixer 1272a mixes the input signal having the non-linear distortion already compensated, with an AC signal. The power amplifier 1273 includes the compound semiconductor device including HEMTs according to any one of the first to eighth embodiments, and amplifies the input signal mixed with the AC signal. In the embodiment, the signal on the output side may be mixed, upon switching, with an AC signal by the mixer 1272b, and may be sent back to the digital predistortion circuit 1271. The amplifier may be used as a high-frequency amplifier or a high-output amplifier.

The composition of each of the compound semiconductor layers is not limited, and a nitride semiconductor such as GaN, AlN, and InN is usable, for instance. A mixed crystal of these is also usable.

In any of the embodiments, the substrate may be a silicon carbide (SiC) substrate, a sapphire substrate, a silicon substrate, a GaN substrate, a GaAs substrate, or the like. The substrate may be conductive, semi-insulative, or insulative.

The structures of the gate electrode, the source electrode, and the drain electrode are not limited to those in the above-described embodiments. For example, they each may be formed of a single layer. Further, a method of forming them is not limited to the lift-off method. Moreover, the heat treatment after the formation of the source electrode and the drain electrode may be dispensed with, provided that the ohmic characteristics can be obtained. The gate electrode may contain Pd and/or Pt in addition to Ni and Au. The numbers of gate electrodes, source electrodes and drain electrodes are not limited to those in the above-described embodiments.

According to the above-described compound semiconductor device and so on, a transistor whose temperature becomes higher during operation has a higher withstand voltage prior to temperature rise due to the operation. This makes it possible for the whole compound semiconductor device to have a sufficient withstand voltage to have excellent reliability even if the temperature increases due to the high-frequency operation.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A compound semiconductor device comprising:
transistors each including a gate electrode, a source electrode, and a drain electrode,
wherein out of the transistors, a transistor whose temperature becomes higher during operation has a higher withstand voltage prior to temperature rise due to the operation.

2. The compound semiconductor device according to claim 1, wherein a distance between the gate electrode and the drain electrode is larger in a transistor whose temperature becomes higher during the operation out of the transistors.

3. The compound semiconductor device according to claim 2, wherein
the transistors are aligned in parallel with a first direction, and
the distance between the gate electrode and the drain electrode is larger in a transistor located closer to a center in the first direction out of the transistors.

4. The compound semiconductor device according to claim 2, wherein, in each of the transistors, a part whose temperature becomes higher during the operation has a larger distance between the gate electrode and the drain electrode in a second direction perpendicular to the first direction.

5. The compound semiconductor device according to claim 1, wherein
the gate electrode includes a first field plate portion on the drain electrode side in each of the transistors, and
the first field plate portion has a larger length in a transistor whose temperature becomes higher during the operation out of the transistors.

6. The compound semiconductor device according to claim 5, wherein
the transistors are aligned in parallel with a first direction, and
the first field plate portion of a transistor located closer to a center in the first direction has a larger length out of the transistors.

7. The compound semiconductor device according to claim 5, wherein, in each of the transistors, a part whose temperature becomes higher during the operation has a larger length of the first field plate portion in a second direction perpendicular to the first direction.

8. The compound semiconductor device according to claim 1, wherein
the transistors each include a second field plate portion insulated from the gate electrode between the gate electrode and the drain electrode in planar view, and
the second field plate portion has a larger length in a transistor whose temperature becomes higher during the operation out of the transistors.

9. The compound semiconductor device according to claim 8, wherein
the transistors are aligned in parallel with a first direction, and
the second field plate portion of a transistor located closer to a center in the first direction has a larger length out of the transistors.

10. The compound semiconductor device according to claim 8, wherein, in each of the transistors, a part whose temperature becomes higher during the operation has a larger length of the second field plate portion in a second direction perpendicular to the first direction.

11. The compound semiconductor device according to claim 1, comprising:
a carrier transit layer; and
a carrier supply layer over the carrier transit layer,
wherein the gate electrodes, the source electrodes and the drain electrodes are above the carrier supply layer.

12. A power supply apparatus, comprising
a compound semiconductor device, wherein the compound semiconductor device comprises:
transistors each including a gate electrode, a source electrode, and a drain electrode,
wherein out of the transistors, a transistor whose temperature becomes higher during operation has a higher withstand voltage prior to temperature rise due to the operation.

13. An amplifier, comprising
a compound semiconductor device, wherein the compound semiconductor device comprises:
transistors each including a gate electrode, a source electrode, and a drain electrode,
wherein out of the transistors, a transistor whose temperature becomes higher during operation has a higher withstand voltage prior to temperature rise due to the operation.

14. A method of manufacturing a compound semiconductor device comprising:
forming transistors each including a gate electrode, a source electrode, and a drain electrode,
wherein out of the transistors, a transistor whose temperature becomes higher during operation has a higher withstand voltage prior to temperature rise due to the operation.
